(19) United States
(12) Patent Application Publication
(10) Pub. No.: US 2017/0176859 A1
(43) Pub. Date: Jun. 22, 2017

(54) PHOTORESIST COMPOSITIONS, METHODS OF FORMING PATTERNS AND METHODS OF MANUFACTURING SEMICONDUCTOR DEVICES

(71) Applicant: SAMSUNG ELECTRONICS CO., LTD., Suwon-si (KR)

(72) Inventors: SOO-YOUNG KIM, SEONGNAM-SI (KR); JAE-HEE CHOI, HWASEONG-SI (KR); JUNG-HOON LEE, HWASEONG-SI (KR); BOO-DEUK KIM, SUWON-SI (KR); JOON-JE LEE, SUWON-SI (KR); YOUN-SOO KIM, SUWON-SI (KR)

(21) Appl. No.: 15/349,578

(22) Filed: Nov. 11, 2016

(30) Foreign Application Priority Data
Dec. 21, 2015 (KR) 10-2015-0182672

(51) Int. Cl. G03F 7/039; G03F 7/038; G03F 7/20; H01L 21/28; G03F 7/32; H01L 27/115; H01L 29/788; G03F 7/004; G03F 7/16

(52) U.S. Cl. CPC G03F 7/039; G03F 7/0045; G03F 7/038; G03F 7/2006; G03F 7/16; G03F 7/168; G03F 7/322; H01L 27/11521; H01L 29/788; H01L 27/11519; H01L 21/28008

(57) ABSTRACT

A photoresist composition comprises a photosensitive resin including a blend of a photoresist polymer and a dye resin, a photo-acid generator, and a solvent, in which an amount of the dye resin is in a range from about 20 weight percent to about 80 weight percent based on a total weight of the photosensitive resin.

### CROSS-REFERENCE TO RELATED APPLICATION

This application claims priority under 35 U.S.C. §119 to Korean Patent Application No. 10-2015-0182672, filed on Dec. 21, 2015, in the Korean Intellectual Property Office (KIPO), the content of which is incorporated by reference herein in its entirety.

### TECHNICAL FIELD

The present invention generally relates to photoresist compositions, methods of forming patterns and methods of manufacturing semiconductor devices, and more particularly, to photoresist compositions including a photosensitive resin, and methods of forming patterns and methods of manufacturing semiconductor devices using the photoresist compositions.

### DISCUSSION OF RELATED ART

A photolithography process may be utilized for forming various patterns included in a semiconductor device. For example, a photoresist layer may be exposed to an actinic radiation or particle beams to cause a chemical reaction in the exposed portion, and for a positive tone photoresist, the exposed portion may then be selectively removed by a developer solution to form a photoresist pattern. For a negative tone photoresist, the unexposed portion may be selectively removed by the developer solution to form a photoresist pattern. An underlying layer for manufacturing semiconductor devices may be patterned using the photoresist pattern as an etching mask to form a desired pattern.

Resolution of the photolithography process may be affected by properties of a light source used in the exposure process, chemical components in a photoresist composition, etc.

### SUMMARY

Example embodiments provide a photoresist composition having an enhanced resolution, a method of forming a pattern using a photoresist composition having an enhanced resolution, and a method of manufacturing a semiconductor device using a photoresist composition having an enhanced resolution.

According to an example embodiment of the present inventive concept, there is provided a photoresist composition that may include a photosensitive resin including a blend of a photoresist polymer and a dye resin, an amount of the dye resin being in a range from about 20 weight percent to about 80 weight percent based on a total weight of the photosensitive resin, a photo-acid generator, and a solvent.

According to an example embodiment of the present inventive concept, there is provided a photoresist composition that may include a photosensitive resin including a photoresist polymer integrally combined with a novolac unit, a photo-acid generator, and a solvent.

According to an example embodiment of the present inventive concept, there is provided a method of forming a pattern. In the method, a photoresist composition may be prepared. The photoresist composition may include a blend of a photoresist polymer and a dye resin, or a photoresist polymer integrally combined with a dye unit. The photoresist composition may be coated directly on a metal layer to form a photoresist layer. An exposure process may be performed on the photoresist layer to form a photoresist pattern. The metal layer may be patterned using the photoresist pattern as an etching mask.

According to an example embodiment of the present inventive concept, there is provided a method of manufacturing a semiconductor device. In the method, memory cells may be formed on a substrate. An insulation layer may be formed on the substrate to cover the memory cells. Contacts electrically connected to the memory cells may be formed through the insulation layer. A metal layer may be formed on the contacts and the insulation layer. A photoresist composition may be coated directly on the metal layer to form a photoresist layer. The photoresist composition may include a blend of a photoresist polymer and a dye resin, or a photoresist polymer integrally combined with a dye unit. An exposure process may be performed on the photoresist layer to form a photoresist pattern. The metal layer may be etched using the photoresist pattern as an etching mask to form a conductive line electrically connected to at least one of the contacts.

According to an example embodiment of the present inventive concept, there is provided a method of forming a pattern. In the method, a substrate may be provided and the substrate may have a metal layer on top. A photoresist layer may be deposited directly on the metal layer. The photoresist layer may include a photoresist polymer which is a polyhydroxystyrene (PHS)-based polymer, a dye resin which is a novolac-based resin, a photo-acid generator which is an onium salt, and an acid quencher which is an amine or an oxide, in which an amount of the dye resin may be in a range from about 25 weight percent to about 75 weight percent based on a total weight of the photoresist polymer and the dye resin combined. The photoresist layer may be patternwise exposed through a photomask with a KrF excimer laser light to form an exposed photoresist layer. The exposed photoresist layer may be developed with an aqueous TMAH developer or an alcohol-based solvent to form a photoresist pattern. The metal layer may be etched using the photoresist pattern as an etching mask.

### BRIEF DESCRIPTION OF THE DRAWINGS

Example embodiments of the present inventive concept will be more clearly understood from the following detailed description taken in conjunction with the accompanying drawings, and in which:

FIGS. 1 to 6 are cross-sectional views illustrating a method of forming a pattern in accordance with an example embodiment of the present inventive concept;

FIGS. 7 to 9 are cross-sectional views illustrating a method of forming a pattern in accordance with an example embodiment of the present inventive concept;

FIGS. 10 to 16 are cross-sectional views illustrating a method of forming a pattern in accordance with an example embodiment of the present inventive concept;

FIGS. 17 to 27 are cross-sectional views illustrating a method of manufacturing a semiconductor device in accordance with an example embodiment of the inventive concept;

FIG. 28 is a cross-sectional view illustrating a semiconductor device in accordance with an example embodiment of the present inventive concept; and

FIGS. 29, 30 and 31 are images of photoresist patterns formed using the photoresist compositions of Examples 1, 2 and 3, respectively, in accordance with an example embodiment of the present inventive concept.

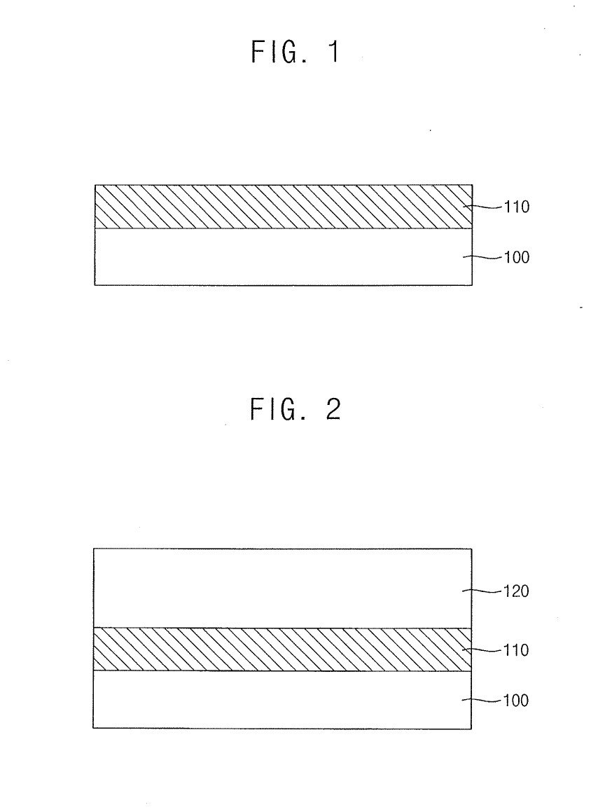

Since the drawings in FIGS. 1-31 are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

Various example embodiments of the present inventive concept will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art.

It will be understood that when an element or layer is referred to as being “on”, “connected to” or “coupled to” another element or layer, it can be directly on, connected or coupled to the other element or layer, or intervening elements or layers may be present. In contrast, when an element or layer is referred to as being “directly on”, “directly connected to” or “directly coupled to” another element or layer, there are no intervening elements or layers present. Like numerals refer to like elements throughout the specification. As used herein, the term “and/or” includes any and all combinations of one or more of the associated listed items.

It will be understood that, although the terms “first”, “second”, “third”, “fourth” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section, or vice versa, without departing from the teachings of the present inventive concept.

Spatially relative terms, such as “beneath”, “below”, “lower”, “above”, “upper” and the like, may be used herein to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” other elements or features would then be oriented “above” the other elements or features. Thus, the exemplary term “below” can encompass both an orientation of above and below. The device may be oriented differently (for example, rotated 90 degrees or at other orientations) and the spatially relative descriptors used herein would then be interpreted accordingly.

The terminology used herein is for the purpose of describing particular example embodiments and is not intended to be limiting of the present inventive concept. As used herein, the singular forms “a”, “an” and “the” are intended to include the plural forms as well, unless the context clearly indicates otherwise.

A photoresist composition in accordance with an example embodiment of the present inventive concept may be utilized in a photo-lithography process for patterning a metal layer. For example, the photoresist composition may be utilized for forming a gate electrode and/or various wiring structures included in a semiconductor device.

In an example embodiment of the present inventive concept, the photoresist composition may include a photosensitive resin, a photo-acid generator (PAG) and a solvent. The photosensitive resin may include a blend of a dye resin and a photoresist polymer, or a photoresist polymer incorporated with a dye unit.

The photoresist polymer may include a polymer used in a positive-type photoresist composition. For example, the photoresist polymer may include a backbone chain of polystyrene, polyhydroxystyrene (PHS), polyacrylate, polymethacrylate, polyvinyl ester, polyvinyl ether, polyolefin, polynorbornene, polyester, polyamide, polycarbonate or the like.

In an example embodiment of the present inventive concept, a PHS-based polymer may be used as the photoresist polymer. In this case, the photoresist polymer may include a repeating unit represented by the following Chemical Formula 1.

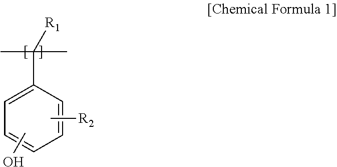

In the Chemical Formula 1, R₁ may represent hydrogen or a C₁˜C₆ alkyl group. R2 may be, e.g., hydrogen, a C₁˜C₆ alkyl group, a C₃˜C₆ cycloalkyl group or a C₁˜C₆ alkoxy group.

In an example embodiment of the present inventive concept, the photoresist polymer may include an acid-labile repeating unit. For example, the acid-labile repeating unit may include an acid-labile protecting group that may be separated by an acid (H⁺). For example, the acid-labile protecting group may include, for example, an acetal group, a ketal group, an ortho ester group, an ether group, a thioether group, a tertiary alkoxycarbonyl group, or a tertiary ester group.

In an example embodiment of the present inventive concept, the dye resin may be blended with the photoresist polymer. In an example embodiment of the present inventive concept, the dye resin may include a novolac-based resin. Novolac resins are phenol-formaldehyde resins, and can be produced by reacting a molar excess of phenol (usually methyl substituted) with formaldehyde in the presence of an acid-catalyst, such as oxalic acid, hydrochloric acid or sulfuric acid. The phenol units are mainly linked by methylene and/or ether groups. For example, the novolac-based resin may include a repeating unit represented by the following Chemical Formula 2.

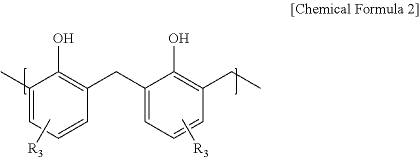

In the Chemical Formula 2, for example, R₃ may be independently hydrogen or a C₁˜C₆ alkyl group.

Chemical Formula 2 exhibits a linear repeating unit with methylene linkages between phenol units at the ortho positions. However, the novolac-based resin may be produced with one or more types of cresols, such as meta-cresol, ortho-cresol, and para-cresol, and may contain methylene linkages at ortho and/or para positions of the phenolic units in the novolac polymer. The novolac polymer may be a linear or a branched polymer.

The novolac-based resin may have a light-absorbent property. For example, the novolac resin may absorb deep UV light. The novolac-based resin may be blended with the photoresist polymer to serve as a dye. Thus, the photoresist polymer blended with the novolac-based resin may serve as a base component of a photoresist having a light-absorbent property.

In an example embodiment of the present inventive concept, an amount of the dye resin may be in a range from about 20 weight percent (wt %) to about 80 wt % based on a total weight of the photosensitive resin. If the amount of the dye resin is less than about 20 wt %, a light reflected from a metal layer by a diffused reflection may not be sufficiently absorbed by the photosensitive resin. If the amount of the dye resin exceeds about 80 wt %, the light-absorbent property may be excessively high, so as to degrade the resolution of a photolithography process.

In an example embodiment of the present inventive concept, the amount of the dye resin may be in a range from about 25 wt % to about 75 wt % based on the total weight of the photosensitive resin. In an example embodiment of the present inventive concept, the amount of the dye resin may be in a range from about 50 wt % to about 75 wt % based on the total weight of the photosensitive resin.

In an example embodiment of the present inventive concept, the dye unit may be integrally combined with the photoresist polymer to be used as the photosensitive resin.

In an example embodiment of the present inventive concept, the photoresist polymer may include a PHS-based polymer, and a novolac unit having a structure represented by, e.g., the Chemical Formula 2 above may be combined with the PHS-based polymer as the dye unit.

In an example embodiment of the present inventive concept, the novolac unit may be combined to at least one aryl ring included in the PHS-based polymer. For example, the novolac unit may be combined to the aryl ring through an ether bond. In this case, the photosensitive resin may include a repeating unit represented by, e.g., the following Chemical Formula 3.

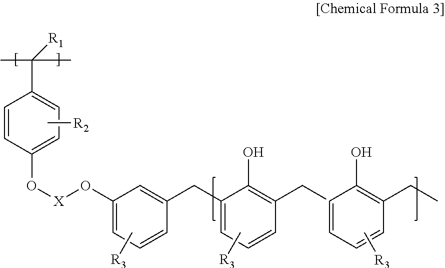

In the Chemical Formula 3, R_{I}, R₂ and R₃ may be substantially the same as those defined in the Chemical Formulae 1 and 2 above.

As indicated in Chemical Formula 3, the novolac unit may be combined with an aryl ring of the PHS-based polymer via a linker group designated as “X”. For example, X may include a C₁˜C₁₀, alkyl group, a C₃˜C₁₀ cycloalkyl group, a C₁˜C₁₀ ether group, a C₃˜C₁₆ diether group or a combination thereof.

In an example embodiment of the present inventive concept, the novolac unit may be combined with at least two aryl rings of the PHS-based polymer. In this case, the novolac unit may include at least two connection points for being combined to different aryl rings included in the PHS-based polymer.

In an example embodiment of the present inventive concept, the novolac unit may be combined with the photoresist polymer, and may serve as a leaving group that may be removed by an acid generated from the PAG during an exposure process.

The PAG may include any compounds capable of generating acids by the exposure process. For example, the PAG may include, but is not limited to, an onium salt, an aromatic diazonium salt, a sulfonium salt, a triarylsulfonium salt, a diarylsulfonium salt, a monoarylsulfonium salt, an iodonium salt, a diaryliodonium salt, nitrobenzyl ester, disulfone, diazo-disulfone, sulfonate, trichloromethyl triazine, N-hydroxysuccinimide triflate, or the like. These may be used alone or in a combination thereof.

The solvent may include an organic solvent having a good solubility for a polymer material, and a good coatability (e.g., good coating characteristics) for a formation of a uniform photoresist layer. Examples of the solvent may include cyclohexanone, cyclopentanone, 2-heptanone, tetrahydrofuran (THF), dimethylformamide, propylene glycol monomethyl ether acetate (PGMEA), ethyl 3-ethoxypropionate, n-butyl acetate, ethyl lactate, methyl ethyl ketone, benzene or toluene. These may be used alone or in a combination thereof.

In an example embodiment of the present inventive concept, the photoresist composition may further include an acid quencher. The acid quencher may prevent the acid generated from the PAG at an exposed portion of a photoresist layer from being excessively diffused. For example, the acid quencher may include tetra-alkylammonium hydroxide, secondary and tertiary amines, pyridinium derivatives and the like.

In an example embodiment of the present inventive concept, the photoresist composition may include an additive such as a sensitizer, a surfactant, etc.

The sensitizer may be added in the photoresist composition to facilitate a formation of the exposed portion by amplifying an amount of photons. Example of the sensitizer may include, but are not limited to, benzophenone, benzoyl, thiophene, naphthalene, anthracene, phenanthrene, pyrene, coumarin, thioxanthone, acetophenone, naphthoquinone, anthraquinone, or the like. These may be used alone or in a combination thereof.

The surfactant may be added in the photoresist composition to facilitate a coating of the photoresist composition. For example, the surfactant may include an ethyleneglycol-based compound.

In an example embodiment of the present inventive concept, the photoresist composition may include the photosensitive resin in a range from about 5 wt % to about 20 wt %, the PAG in a range from about 0.1 wt % to about 1 wt %, the acid quencher in a range from about 0.01 wt % to about 0.5 wt %, the additive in a range from about 0.01 wt % to about 1 wt %, and the solvent in a range from about 78 wt % to about 94 wt %.

As described above, the photoresist composition according to an example embodiment of the present inventive concept may include the photosensitive resin that may include the dye resin or the dye unit. Accordingly, a light from a metal layer by a diffused reflection may be effectively absorbed, and a desired photosensitive property may be maintained to obtain a better resolution of a photo-lithography process.

As described above, the photoresist composition may include, e.g., the novolac resin or the novolac unit having the light-absorbent property. The novolac resin or the novolac unit may be employed in an exposure process using, e.g., radiation generated from an I-line source. I-line source is a mercury vapor lamp and provides 365 nm light for photoresist exposure. The novolac resin or the novolac unit may be blended or combined with the PHS-based polymer, so that the photoresist composition may be also utilized in an exposure process using, e.g., a light generated from a KrF light source. KrF light source is a krypton-fluoride excimer laser and provides a KrF excimer laser light with 248 nm wavelength for photoresist exposure. Thus, a pattering process of the metal layer may be implemented with more enhanced resolution.

FIGS. 1 to 6 are cross-sectional views illustrating a method of forming a pattern in accordance with an example embodiment of the present inventive concept. For example, FIGS. 1 to 6 illustrate a method of forming a pattern utilizing the above-mentioned photoresist composition.

Referring to FIG. 1, an object layer 110 may be formed on a substrate 100. The substrate 100 may include a semiconductor substrate or a semiconductor-on-insulator substrate. For example, the substrate 100 may include a silicon substrate, a germanium substrate, a silicon-germanium substrate, a silicon-on-insulator (SOI) substrate or a germanium-on-insulator (GOI) substrate. In an example embodiment of the present inventive concept, the substrate 100 may include a group III-V compound such as GaP, GaAs or GaSb.

An image may be transferred from a photoresist pattern to the object layer 110, so that the object layer 110 may be converted to a desired (or predetermined) pattern. In an example embodiment of the present inventive concept, the object layer 110 may be formed substantially as a metal layer. For example, the object layer 110 may be formed of a metal such as copper, tungsten, aluminum, cobalt, titanium, tantalum, or the like, by a sputtering process, an atomic layer deposition (ALD) process, a physical vapor deposition (PVD) process, a chemical Vapor Deposition (CVD) or a plating process.

Referring to FIG. 2, a photoresist layer 120 may be formed on the object layer 110.

The photoresist composition according to an example embodiment of the present inventive concept as described above may be coated on the object layer 110 by, e.g., a spin coating process, a dip coating process, a spray coating process, or the like. In an example embodiment of the present inventive concept, the photoresist composition may be coated to form a preliminary photoresist layer, and the preliminary photoresist layer may be baked to remove the solvent by a soft-baking process to form the photoresist layer 120.

In an example embodiment of the present inventive concept, the photoresist layer 120 may be formed directly on a top surface of the object layer 110.

As described above, the photoresist composition may include a photosensitive resin, a PAG and a solvent. The photosensitive resin may include a blend of a dye resin and a photoresist polymer, or a photoresist polymer incorporated with a dye unit.

In an example embodiment of the present inventive concept, a PHS-based polymer including a repeating unit as represented by the Chemical Formula 1 above may be utilized as the photoresist polymer. The PHS-based polymer may include a styrene repeating unit and an acid-labile repeating unit containing an acid-labile protecting group.

In an example embodiment of the present inventive concept, a novolac-based resin including a repeating unit represented by the Chemical Formula 2 above may be used as the dye resin. The dye unit may include a novolac unit.

If the photosensitive resin includes a blend of the photoresist polymer and the dye resin, an amount of the dye resin may be in a range from about 20 wt % to about 80 wt % based on a total weight of the photosensitive resin.

If the photosensitive resin includes the photoresist polymer integrally incorporated with the dye unit, the novolac unit may be combined to at least one aryl ring included in the PHS-based polymer as represented by the Chemical Formula 3 above.

The photoresist composition may further include an acid quencher, and may further include an additive such as a sensitizer and/or a surfactant.

In an example embodiment of the present inventive concept, the photoresist composition may include the photosensitive resin in a range from about 5 wt % to about 20 wt %, the PAG in a range from about 0.1 wt % to about 1 wt %, the acid quencher in a range from about 0.01 wt % to about 0.5 wt %, the additive in a range from about 0.01 wt % to about 1 wt %, and the solvent in a range from about 78 wt % to about 94 wt %.

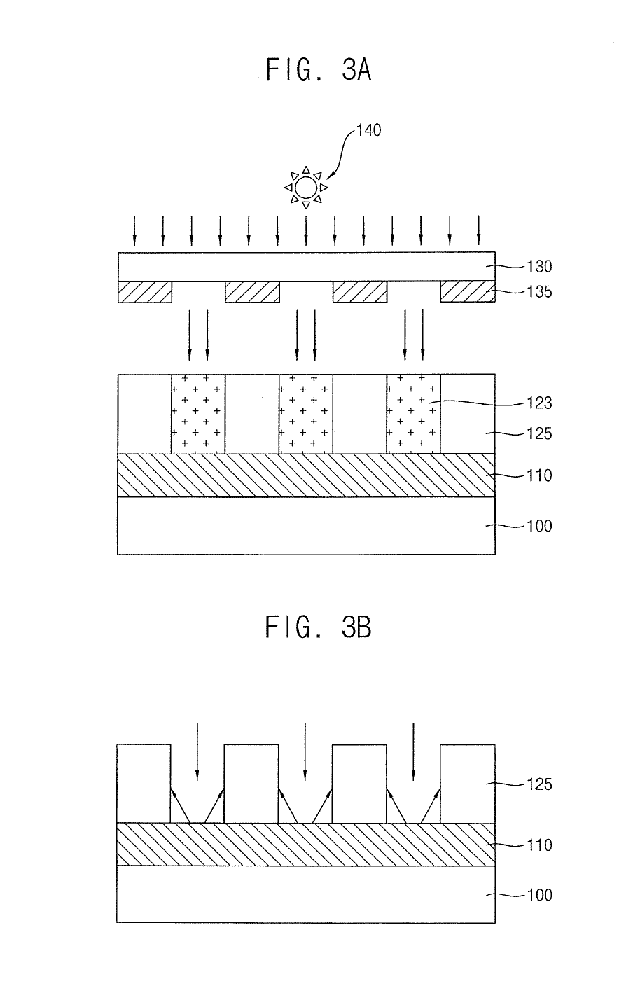

Referring to FIGS. 3A an 3B, an exposure process may be performed on the photoresist layer 120 to form an exposed portion 123 and a non-exposed portion 125.

In an example embodiment of the present inventive concept, as illustrated in FIG. 3A, an exposure mask including a transparent substrate 130 and a light-shielding portion 135 may be placed over the photoresist layer 120. The transparent substrate 130 may include, e.g., glass or quartz. The light-shielding portion 135 may include a metal, e.g., chromium.

A light may be generated from a light source 140 toward the exposure mask, and the light through a portion of the transparent substrate 130 between the light-shielding portions 135 may be irradiated on the photoresist layer 120. The light source 140 may include a source of, e.g., ArF, KrF, an electron beam, I-line, extreme ultraviolet (EUV), etc. In an example embodiment of the present inventive concept, a KrF light source may be utilized as the light source.

A portion of the photoresist layer on which the light through the exposure mask may be irradiated may be transformed into the exposed portion 123. A remaining portion of the photoresist layer 120 except for the exposed portion 123 may be defined as the non-exposed portion 125.

An acid may be generated from the PAG at the exposed portion 123 so that the protecting group included in the photoresist polymer may be deprotected. A polar group or a hydrophilic group such as a hydroxyl group or a carboxyl group may be created at a site from which the protecting group is removed at the exposed portion 123. Thus, a solubility of the exposed portion 123 with respect to a developer solution, e.g., a hydrophilic solution, used in a subsequent developing process may be increased.

In an example embodiment of the present inventive concept, if the dye unit is incorporated with the photoresist polymer, a reaction may be induced at the exposed portion 123 according to, e.g., the following reaction mechanism.

[Before Exposure Process]

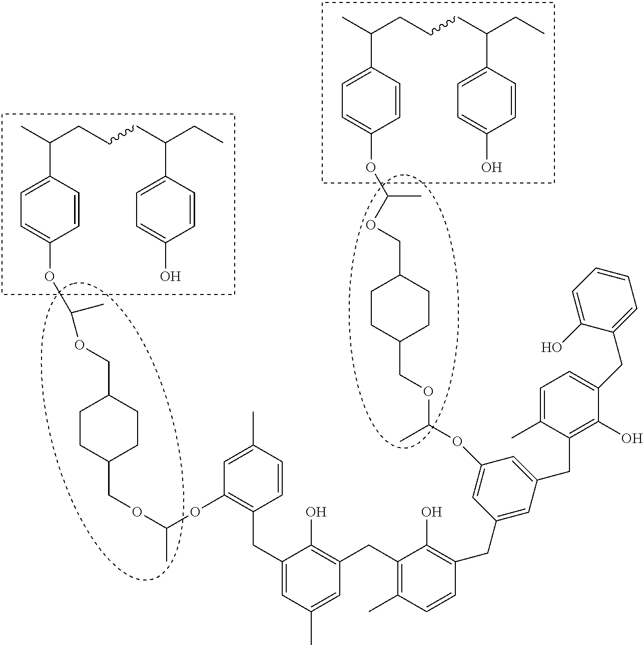 [SMILES: CCC(CCCC(C)c1ccc(OC(C)OCC2CCC(COC(C)Oc3cc(Cc4ccc(C)c(Cc5cc(C)cc(Cc6ccc(C)cc6OC(C)OCC6CCC(COC(C)Oc7ccc(C(C)CCCC(CC)c8ccc(O)cc8)cc7)CC6)c5O)c4O)cc(Cc4c(C)ccc(Cc5ccccc5O)c4O)c3)CC2)cc1)c1ccc(O)cc1]

Before the exposure process, the novolac unit as the dye unit may be connected to an aryl ring of a PHS-based polymer (designated as a dotted quadrangle) via a linker group (designated as a dotted ellipse). As represented in the structural formula above, the novolac unit may be connected to a plurality of the aryl rings via a plurality of the linker groups, and may include a plurality of connection points.

[After Exposure Process]

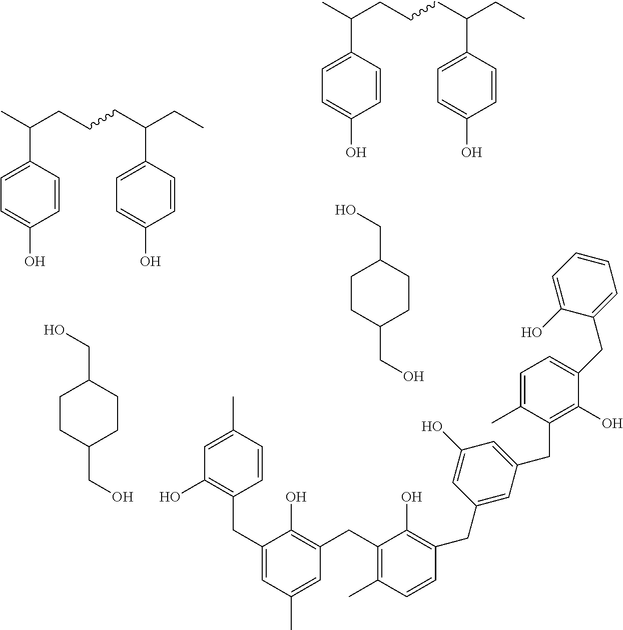 [SMILES: CCC(CCCC(C)c1ccc(O)cc1)c1ccc(O)cc1 ; OCC1CCC(CO)CC1 ; Cc1ccc(Cc2cc(C)cc(Cc3c(C)ccc(Cc4cc(O)cc(Cc5c(C)ccc(Cc6ccccc6O)c5O)c4)c3O)c2O)c(O)c1 ; CCC(CCCC(C)c1ccc(O)cc1)c1ccc(O)cc1 ; OCC1CCC(CO)CC1]

An acid (H⁺) may be generated from the PAG by the exposure process, so that the connection points between the linker groups and the PHS-based polymer, and between the linker groups and the novolac unit may be separated. Hydroxyl groups may be created at the connection points, and thus polar and/or hydrophilic properties of the exposed portion 123 may increase.

As described with reference to the reaction mechanism, the dye unit may be combined to the photoresist polymer as a leaving group capable of being separated by the acid.

As illustrated in FIG. 3B (for convenience of descriptions, an illustration of the exposed portion 123 is omitted in FIG. 3B), when the object layer 110 is the metal layer, the light irradiated by the exposure process may be reflected from a surface of the object layer 100 to cause a diffused reflection. The reflected light may penetrate into the non-exposed portion 125 to deteriorate a resolution of a photolithography process.

According to an example embodiment of the present inventive concept, the light scattered from the object layer 110 by the diffused reflection may be absorbed by the photoresist layer 120, or the dye resin or the dye unit included therein. Additionally, the dye unit may serve as the leaving group separated by an acid to facilitate a formation of the exposed portion 123.

In a comparative example, an anti-reflective layer may be formed between the object layer 110 and the photoresist layer 120 for preventing the diffused reflection. The anti-reflective layer may be formed of an organic-based or inorganic-based material. If the object layer 110 includes a metal, an inorganic-based anti-reflective layer may be formed of, e.g., titanium nitride (TiN) for reducing a damage of the metal. In the comparative example, an additional layer deposition may be added to form the anti-reflective layer, and an etching process with respect to the anti-reflective layer may be also added before patterning the object layer 110. Further, a process for removing the anti-reflective layer after completing a photo-lithography process may be also needed.

According to the example embodiments of the present inventive concept described above, the photoresist layer 120 may include the dye resin or the dye unit, so that the photoresist layer 120 may have a light-absorbent property, and the anti-reflective layer may not be formed. Thus, better efficiency and higher productivity of a patterning process or a photo-lithography process may be obtained.

In an example embodiment of the present inventive concept, a post exposure baking (PEB) process may be further performed after the exposure process. The acid generated during the exposure process may be uniformly distributed throughout the exposed portion 123 by the PEB process. Most chemically amplified photoresists depend on the PEB process to drive the acid catalyzed deprotection reaction. For the photoresist systems having extremely acid labile groups, PEB step may not be needed, but the PEB process will enhance the deprotection reaction.

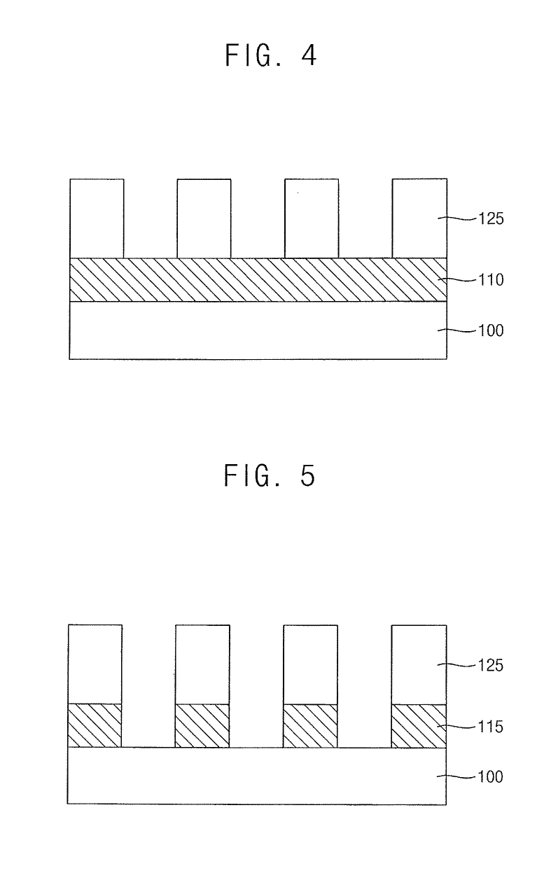

Referring to FIG. 4, the exposed portion 123 of the photoresist layer 120 may be selectively removed by a developing process. Accordingly, a photoresist pattern may be defined by the non-exposed portion 125 remaining on the object layer 110.

An alcohol-based solution, or a hydroxide-based aqueous solution including, e.g., aqueous tetra methyl ammonium hydroxide (TMAH) solution may be used as a developer solution in the developing process. As described above, the exposed portion 123 may become more polar or hydrophilic than the non-exposed portion 125 through a photochemical reaction, and may become soluble to the developer solution. The more polar or hydrophilic property of the exposed portion renders the exposed portion more soluble in hydrophilic solution. Thus, only the exposed portion 123 may be removed by the developer solution such as aqueous TMAH solution.

Referring to FIG. 5, the object layer 110 may be etched using the photoresist pattern defined by the non-exposed portion 125. Accordingly, a target pattern 115 may be formed from the object layer 110 between the substrate 100 and the non-exposed portion 125.

The etching process may include a dry etching process and/or a wet etching process properly selected in consideration of an etching selectivity between the photoresist pattern and the metal. For example, the etching process may include the wet etching process using an etchant solution such as a peroxide-based solution.

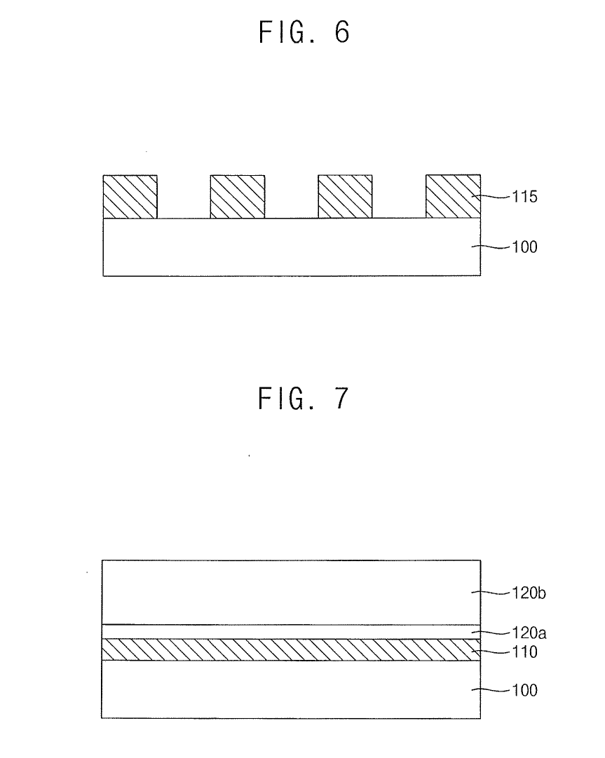

Referring to FIG. 6, the photoresist pattern may be removed such that the target pattern 115 may remain on the substrate 100.

In an example embodiment of the present inventive concept, the photoresist pattern may be removed by an aching process and/or a strip process. The target pattern 115 may serve as a conductive pattern of a semiconductor device, e.g., a wiring, a contact, a plug, a pad, etc.

As described with reference to FIGS. 1 to 6, the photoresist composition may be the positive-type photoresist. However, the photoresist composition may be utilized as a negative-type photoresist. In this case, for example, a hydroxyl group included in a styrene unit may be removed at the exposed portion 123, and thus a polarity of the exposed portion 123 may be reduced, or a hydrophobicity of the exposed portion 123 may be increased. In addition, a crosslinking agent may be added to the photoresist composition, so that the exposed portion will have acid catalyzed crosslinking between the photoresist polymers to reduce solubility in developer. A reflected light may be absorbed by the dye resin blended in the photosensitive resin. The non-exposed portion 125 may be selectively removed by a developing process, and the exposed portion 123 may remain on the object layer 110 to serve as a photoresist pattern. The crosslinking agents preferably act to crosslink the polymeric component in the presence of a generated acid. Suitable organic crosslinking agents include, but are not limited to: amine-containing compounds, epoxy-containing compounds, compounds containing at least two vinyl ether groups, allyl substituted aromatic compounds, compounds containing at least two or more diazonaphthoquinone sulfonic acid ester groups and combinations thereof. Preferred crosslinking agents are glycoluril compounds such as tetramethoxymethyl glycoluril, methylpropyltetramethoxymethyl glycoluril, and methylphenyltetramethoxymethyl glycoluril, available under the POWDERLINK trademark from Cytec Industries, Inc. Other preferred crosslinking agents include 2,6-bis(hydroxymethyl)-p-cresol, methylated or butylated melamine resins (N-methoxymethyl- or N-butoxymethyl-melamine respectively), methylated/butylated glycolurils, bis-epoxies or bis-phenols (e.g., bisphenol-A). Combinations of crosslinking agents may be used.

FIGS. 7 to 9 are cross-sectional views illustrating a method of forming a pattern in accordance with an example embodiment of the present inventive concept. Detailed descriptions on processes and/or materials substantially the same as or similar to those illustrated with reference to FIGS. 1 to 6 are omitted herein.

Referring to FIG. 7, as also illustrated in FIG. 1, an object layer 110 may be formed on a substrate 100. The object layer 110 may be formed of a metal.

A first photoresist layer 120a and a second photoresist layer 120b may be sequentially formed on the object layer 110.

The first photoresist layer 120a may serve as an underlayer for improving an adhesion between the object layer 110 and the second photoresist layer 120b. In an example embodiment of the present inventive concept, the first photoresist layer 120a may include a polymer having a backbone structure substantially the same as or similar to that of the second photoresist layer 120b, and may further include an adhesion unit or a wetting unit. The adhesion unit or a wetting unit may include, e.g., an ester group, a ketone group and/or a lactone group. In an example embodiment of the present inventive concept, the first photoresist layer 120a may be formed directly on a top surface of the object layer 110. The first photoresist layer 120a may or may not include a PAG.

The second photoresist layer 120b may have a composition or a construction substantially the same as that of the photoresist layer 120 of FIG. 2. The second photoresist layer 120b may be formed of the photoresist composition according to the example embodiments as described above. The photoresist composition may include a photosensitive resin that may contain a photoresist polymer blended with dye resin, or a photoresist polymer incorporated with a dye unit.

In an example embodiment of the present inventive concept, the dye resin or the dye unit may be also included in the first photoresist layer 120a.

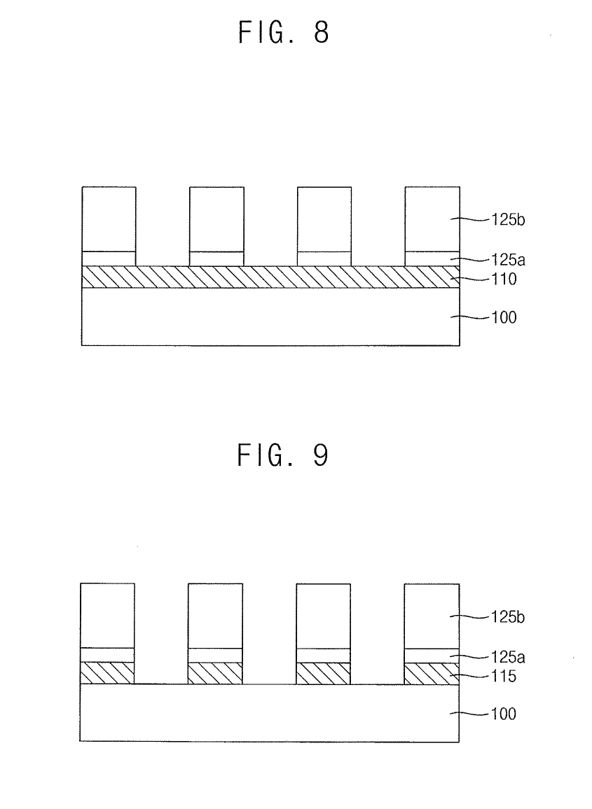

Referring to FIG. 8, processes substantially the same as or similar to those described with reference to FIGS. 3A, 3B and 4 may be performed.

In an example embodiment of the present inventive concept, the second photoresist layer 120b may be divided into a second exposed portion and a second non-exposed portion 125b by an exposure process. In an example embodiment of the present inventive concept, an acid generated from a PAG at the second exposed portion may be diffused into a portion of the first photoresist layer 120a under the second exposed portion. Accordingly, the first photoresist layer 120a may be divided into a first exposed portion and a first non-exposed portion 125a.

The second and first exposed portions may be removed by a developing process. A photoresist pattern including the first non-exposed portion 125a and the second non-exposed portion 125b may be formed on the object layer 110.

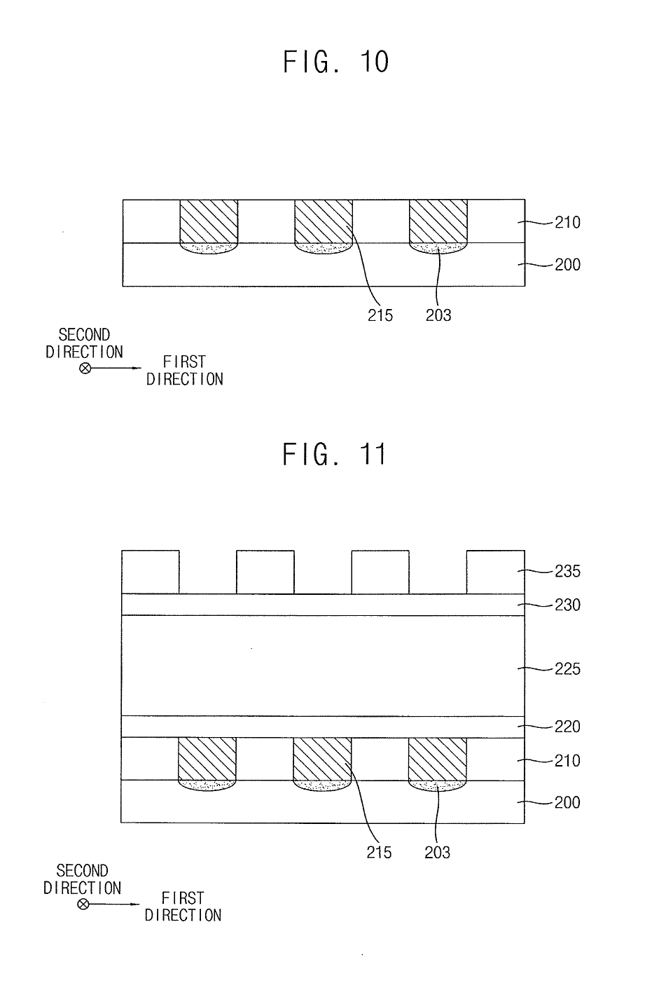

Referring to FIG. 9, as also described with reference to FIG. 5, the object layer 110 may be partially etched using the photoresist pattern as an etching mask. Accordingly, a target pattern 115 may be formed from the object layer 110. Subsequently, as also described with reference to FIG. 6, the photoresist pattern on the target pattern 115 may be removed by, e.g., an ashing process and/or a strip process.

FIGS. 10 to 16 are cross-sectional views illustrating a method of forming a pattern in accordance with an example embodiment of the present inventive concept. Detailed descriptions on processes and/or materials substantially the same as or similar to those described with reference to FIGS. 1 to 6 are omitted herein.

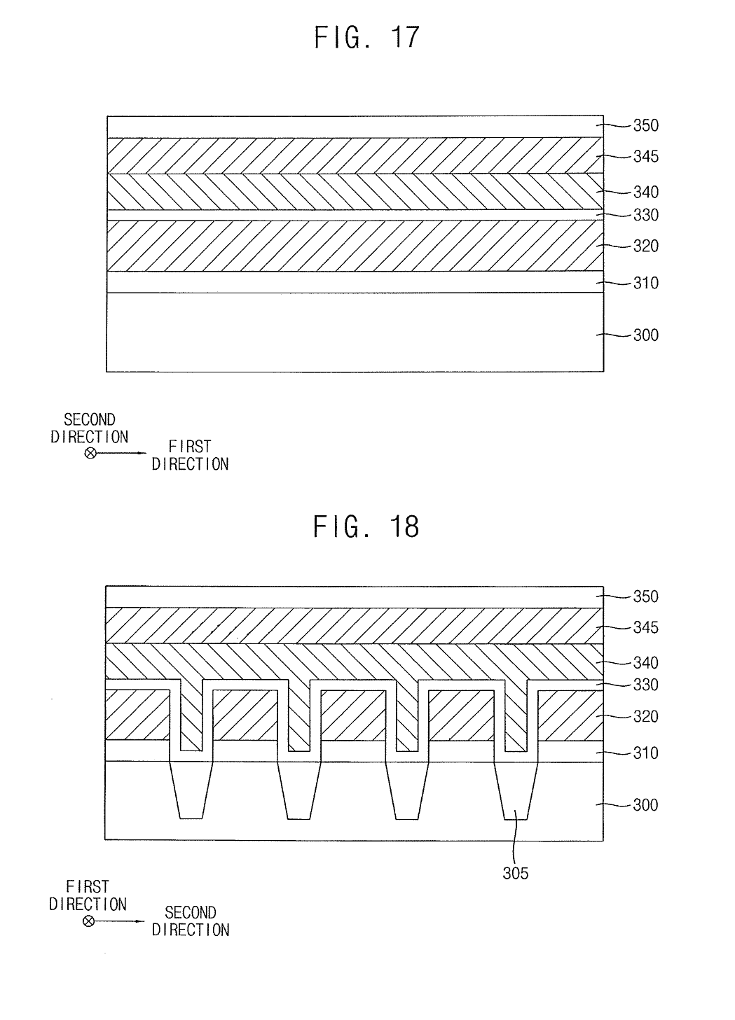

In FIGS. 10 to 16, two directions substantially parallel to a top surface of a substrate and substantially perpendicular to each other may be defined as a first direction and a second direction. The definitions of the direction are the same in FIGS. 17 to 27.

Referring to FIG. 10, a lower insulation layer 210 may be formed on a substrate 200, and a lower contact 215 may be formed in the lower insulation layer 210.

In an example embodiment of the present inventive concept, a contact hole may be formed in the lower insulation layer 210, and an ion-implantation process may be performed through the contact hole to form an impurity region 203 at an upper portion of the substrate 200. The contact hole may be filled with a first conductive layer by a deposition process or a plating process to form the lower contact 215. The lower contact 215 may be electrically connected to the impurity region 203.

The lower insulation layer 210 may be formed of, e.g. silicon oxide or silicon oxynitride. For example, the lower insulation layer 210 may be formed of, e.g., plasma enhanced oxide (PEOX), tetraethyl orthosilicate (TEOS), phospho silicate glass (PSG), borosilicate glass (BSG), etc.

Referring to FIG. 11, a first etch-stop layer 220, an insulating interlayer 225 and a second etch-stop layer 230 may be sequentially formed on the lower insulation layer 210 and the lower contacts 215. A hard mask 235 may be formed on the second etch-stop layer 230.

The first and second etch-stop layers 220 and 230 may be formed of, e.g., silicon nitride or silicon oxynitride. The insulating interlayer 225 may be formed of silicon oxide, or a low dielectric (low-k) oxide such as, e.g., polysiloxane or silsesquioxane. The first etch-stop layer 220, the insulating interlayer 225 and a second etch-stop layer 230 may be formed by, e.g., a CVD process, an ion-beam sputtering process, a spin coating process, etc.

The hard mask 235 may be formed of a silicon-based or carbon-based spin-on hard mask (SOH) material. A top surface of the second etch-stop layer 230 may be partially exposed through the hard mask 235.

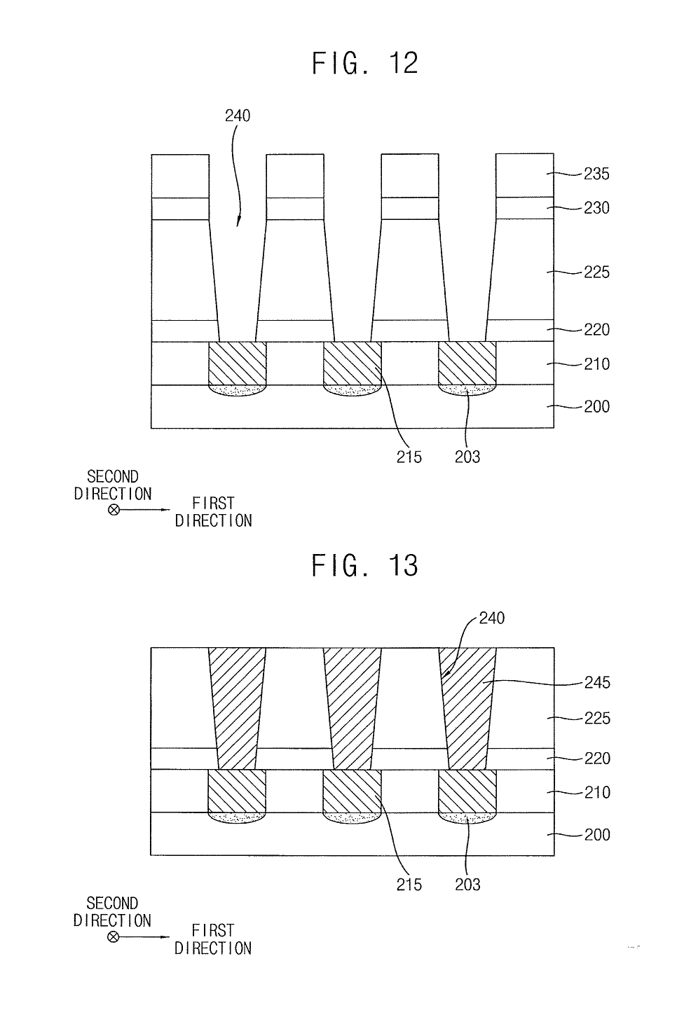

Referring to FIG. 12, the second etch-stop layer 230, the insulating interlayer 225 and the first etch-stop layer 220 may be partially and sequentially etched using the hard mask 235 as an etching mask to form an opening 240.

In an example embodiment of the present inventive concept, a top surface of the lower contact 215 may be exposed through the opening 240. For example, the opening 240 may have a contact hole shape through which each lower contact 215 may be exposed. In an example embodiment of the present inventive concept, the opening 240 may have a linear shape extending in the second direction through which a plurality of the lower contacts 215 may be exposed. A plurality of the openings 240 may be formed along the first direction.

The hard mask 235 may be removed by, e.g., an ashing process after forming the openings 240.

Referring to FIG. 13, a conductive pattern 245 may be formed in the opening 240.

In an example embodiment of the present inventive concept, a second conductive layer filling the openings 240 may be formed on the second etch-stop layer 230. An upper portion of the second conductive layer may be planarized by a chemical mechanical polishing/planarization (CMP) process until a top surface of the insulating interlayer 225 is exposed to form the conductive patterns 245. The second conductive layer may be formed of a metal such as, e.g., copper, aluminum, tungsten, or the like, by a sputtering process or an ALD process.

In an example embodiment of the present inventive concept, a barrier conductive layer may be formed on an inner wall of the opening 240 before forming the second conductive layer. The barrier conductive layer may be formed of a metal nitride such as, e.g., titanium nitride or tantalum nitride.

In an example embodiment of the present inventive concept, the second conductive layer may be formed by a plating process. For example, a seed layer may be formed conformally on the barrier conductive layer by a sputtering process using a copper target. Subsequently, an electroplating process may be performed so that the second conductive layer including copper may be grown or precipitated on the seed layer to fill the openings 240.

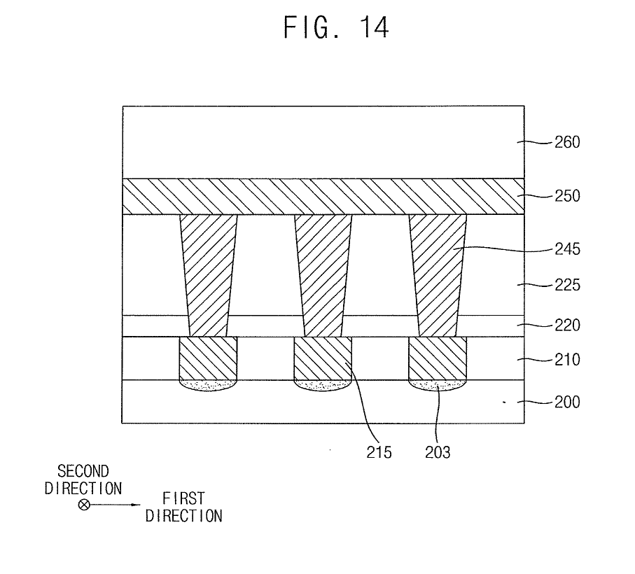

Referring to FIG. 14, a third conductive layer 250 may be formed on the insulating interlayer 225 and the conductive patterns 245, and a photoresist layer 260 may be formed on the third conductive layer 250.

In an example embodiment of the present inventive concept, the third conductive layer 250 may be formed of a metal such as, e.g., copper, aluminum, tungsten, or the like, by a sputtering process or an ALD process.

The photoresist layer 260 may be formed from a process and a photoresist composition substantially the same as or similar to those described with reference to FIG. 2. The photoresist layer 260 may be formed directly on a top surface of the third conductive layer 250, and an additional layer including an anti-reflective layer may be omitted. In an example embodiment of the present inventive concept, the photoresist layer 260 may be formed as a multi-layered structure including first and second photoresist layers as described with reference to FIG. 7.

As described above, the photoresist composition may include a photosensitive resin, a PAG and a solvent. The photosensitive resin may include a blend of a dye resin and a photoresist polymer, or a photoresist polymer incorporated with a dye unit.

In an example embodiment of the present inventive concept, a PHS-based polymer including a repeating unit as represented by the Chemical Formula 1 above may be utilized as the photoresist polymer. The PHS-based polymer may include a styrene repeating unit and an acid-labile repeating unit including an acid-labile protecting group.

In an example embodiment of the present inventive concept, a novolac-based resin including a repeating unit represented by the Chemical Formula 2 above may be used as the dye resin. The dye unit may include a novolac unit.

If the photosensitive resin includes a blend of the photoresist polymer and the dye resin, an amount of the dye resin may be in a range from about 20 wt % to about 80 wt % based on a total weight of the photosensitive resin.

If the photosensitive resin includes the photoresist polymer integrally incorporated with the dye unit, the novolac unit may be combined to at least one aryl ring included in the PHS-based polymer as represented by the Chemical Formula 3 above.

The photoresist composition may further include an acid quencher, and may further include an additive such as a sensitizer and/or a surfactant.

In an example embodiment of the present inventive concept, the photoresist composition may include the photosensitive resin in a range from about 5 wt % to about 20 wt %, the PAG in a range from about 0.1 wt % to about 1 wt %, the acid quencher in a range from about 0.01 wt % to about 0.5 wt %, the additive in a range from about 0.01 wt % to about 1 wt %, and the solvent in a range from about 78 wt % to about 94 wt %.

Referring to FIG. 15, process substantially the same as or similar to those illustrated with reference to FIGS. 3A and 4 may be performed. In an example embodiment of the present inventive concept, the photoresist layer 260 may be partially removed by exposure and developing processes. For example, an exposed portion of the photoresist layer 260 may be removed to form a photoresist pattern 265.

While performing the exposure process, a diffusively reflected light may be absorbed by the dye resin or the dye unit included in the photosensitive resin so that the photoresist patterns 265 may achieve high resolution.

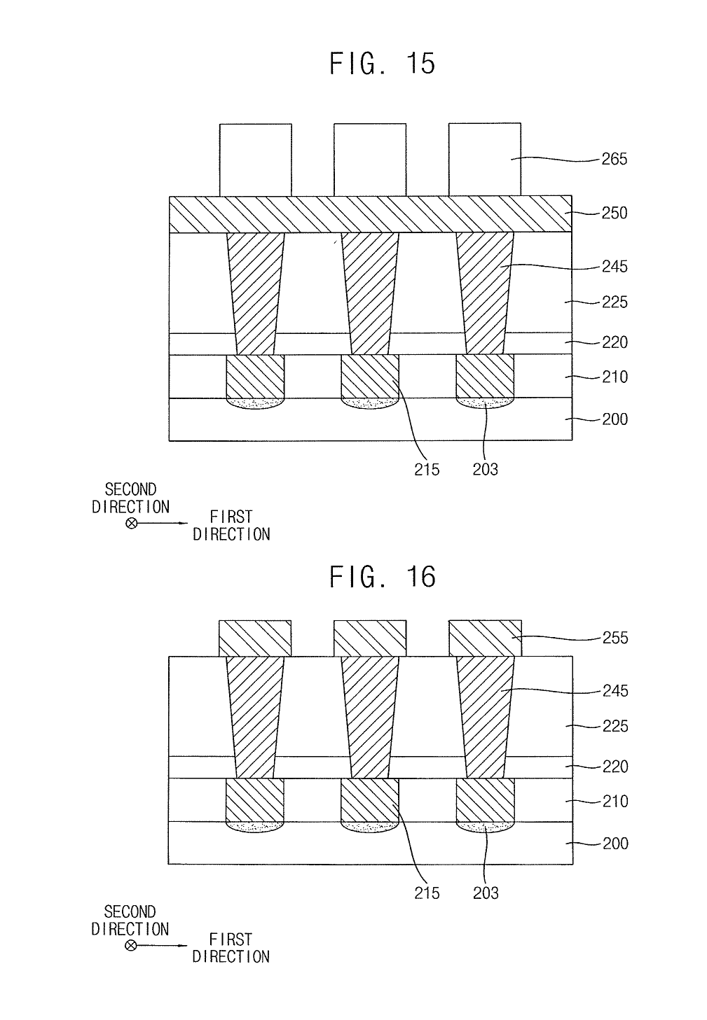

Referring to FIG. 16, the third conductive layer 250 may be patterned using the photoresist pattern 265 as an etching mask. Accordingly, a wiring 255 electrically connected to the conductive pattern 245 may be formed from the third conductive layer 250.

The wiring 255 may extend in, e.g., the second direction, and may be electrically connected to a plurality of the conductive patterns 245.

As described above, the wiring of a fine pitch or a fine line width included in a semiconductor device may be formed using the photoresist composition according to an example embodiment of the present inventive concept with a high resolution.

FIGS. 17 to 27 are cross-sectional views illustrating a method of manufacturing a semiconductor device in accordance with an example embodiment of the present inventive concept. For example, FIGS. 17 to 27 illustrate a method of manufacturing a planar-type non-volatile flash memory device. The memory cells may include volatile memory cells and non-volatile memory cells. Flash memory cells are non-volatile memory cells and may include planar-type flash memory cells and non-planar-type (3-dimensional) flash memory cells.

Specifically, FIGS. 17, 19, 21, 22, 23 and 26 are cross-sectional views taken along the first direction. FIGS. 18, 20, 24, 25 and 27 are cross-sectional views taken along the second direction.

Referring to FIGS. 17 and 18, a tunnel insulation layer 310, a charge storage layer 320, a dielectric layer 330, a first control gate layer 340, a second control gate layer 345 and a gate mask layer 350 may be sequentially formed on a substrate 300.

The substrate 300 may include, e.g., a silicon substrate, a germanium substrate, a silicon-germanium substrate, an SOI substrate, a GOI substrate, etc. The substrate 300 may include a group III-V compound, such as, e.g., InP, GaP, GaAs, GaSb, or the like.

The tunnel insulation layer 310 may be formed of, e.g., silicon oxide, silicon nitride and/or silicon oxynitride. In an example embodiment of the present inventive concept, the tunnel insulation layer 310 may be formed as a multi-layered structure, such as, e.g., an oxide-nitride-oxide (ONO)-layered structure or an oxide-silicon-oxide (OSO)-layered structure.

The charge storage layer 320 may be formed by a deposition process using a silicon precursor, and p-type or n-type impurities. The charge storage layer 320 may be formed of doped polysilicon. For example, the charge storage layer 320 may serve as a floating gate layer.

In an example embodiment of the present inventive concept, as illustrated in FIG. 18, after the formation of the charge storage layer 320, the charge storage layer 320, the tunnel insulation layer 310 and an upper portion of the substrate 300 may be partially etched substantially along the first direction to form an isolation trench. The substrate 300 may be divided into an active region and a field region by the isolation trench. An isolation layer 305 partially filling the isolation trench may be formed of, e.g., silicon oxide. The charge storage layer 320 and the tunnel insulation layer 310 may be converted into linear patterns extending substantially in the first direction on the active region by the above-mentioned process.

Subsequently, the dielectric layer 330, the first control gate layer 340, the second control gate layer 345 and the gate mask layer 350 may be sequentially formed on the charge storage layer 320 and the isolation layer 305.

The dielectric layer 330 may be formed as a single-layered structure of an oxide layer or a nitride layer, or a multi-layered structure, such as an ONO-layered structure. In an example embodiment of the present inventive concept, the dielectric layer 330 may be formed of a high-k metal oxide. The dielectric layer 330 may have a substantially wavy profile along surfaces of the charge storage layer 320, the tunnel insulation layer 310 and the isolation layer 305.

The first control gate layer 340 may fill remaining portions of the isolation trench on the dielectric layer 330. In an example embodiment of the present inventive concept, the first control gate layer 340 may be formed of doped polysilicon. The second control gate layer 345 may be formed of a metal or a metal silicide. The gate mask layer 350 may be formed of silicon nitride or silicon oxynitride.

The tunnel insulation layer 310, the charge storage layer 320, the dielectric layer 330, the first control gate layer 340, the second control gate layer 345 and the gate mask layer 350 may be formed by, e.g., at least one of a CVD process, a plasma enhanced chemical vapor deposition (PECVD) process, a sputtering process, a physical vapor deposition (PVD) process and an ALD process.

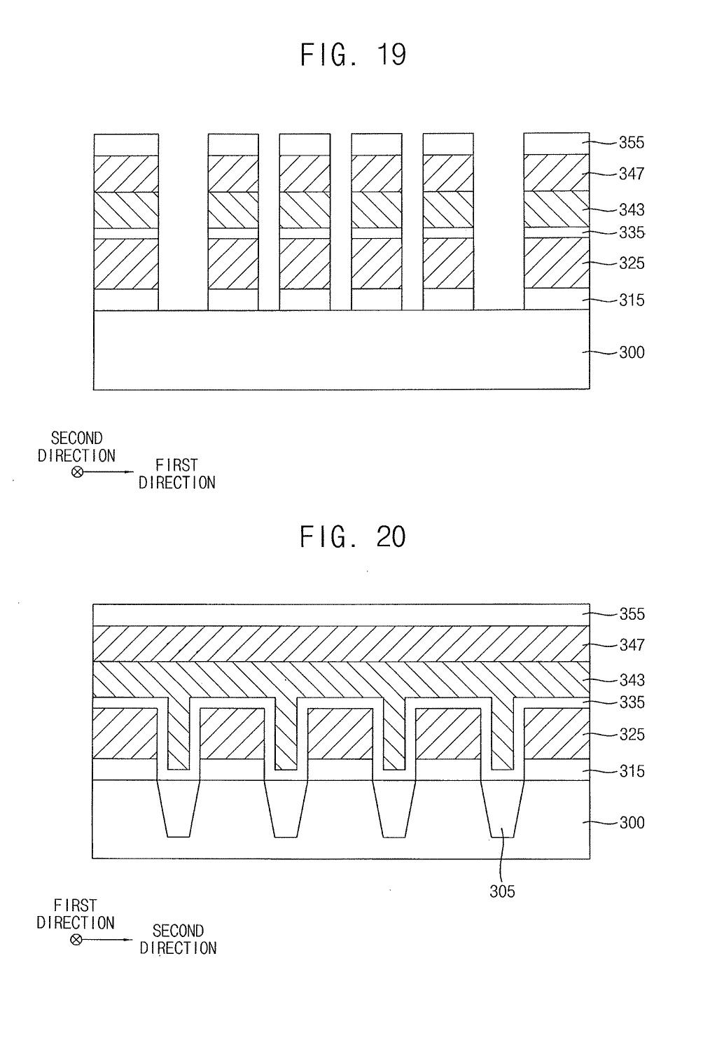

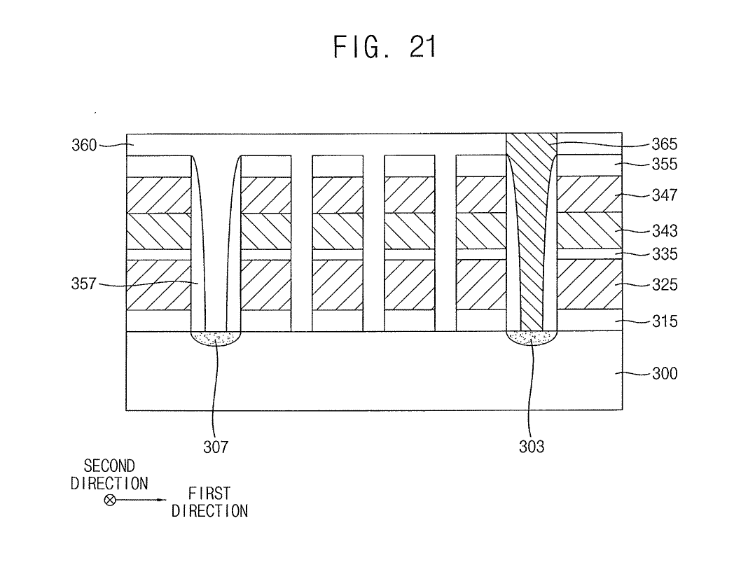

Referring to FIGS. 19 and 20, the gate mask layer 350 may be partially etched along substantially the second direction to form a plurality of gate masks 355. The second control gate layer 345, the first control gate layer 340, the dielectric layer 330, the charge storage layer 320 and the tunnel insulation layer 310 may be sequentially and partially etched using the gate masks 355 as an etching mask. Accordingly, gate structures, each of which may include a tunnel insulation pattern 315, a charge storage pattern 325, a dielectric pattern 335, a first control gate 343, a second control gate 347 and the gate mask 355 sequentially stacked on a top surface of the substrate 300, may be formed.

A portion of each gate structure, for example, the dielectric pattern 335, the first control gate 343, the second control gate 347 and the gate mask 355 may have linear shapes continuously extending substantially in the second direction. The charge storage pattern 325 and the tunnel insulation pattern 315 may have island shapes spaced apart from each other along the first and second directions. In an example embodiment of the present inventive concept, the tunnel insulation layer 310 may not be completely removed between the gate structures neighboring each other by the above etching process. In this case, the tunnel insulation pattern 315 may have a linear shape extending in the first direction.

A central portion of the substrate 300 may correspond to a cell region. The gate structures may be formed on the cell region by relatively narrow width and pitch, and may serve as memory cells. FIG. 19 illustrates that four gate structures are formed on the cell region. However, the number of the gate structures on the cell region may not be specifically limited.

Peripheral portions of the substrate 300 adjacent to the cell region may correspond to a selection region. The gate structures may be formed on the selection region by relatively large width and pitch.

In an example embodiment of the present inventive concept, the charge storage pattern 325 and the first control gate 343 of the gate structure formed on the selection region may be electrically connected to or in contact with each other. In this case, portions of the charge storage layer 320 and the first control gate layer 340 on the selection region may be connected to each other by a butting process during a process illustrated with reference to FIG. 17.

Referring to FIG. 21, a gate spacer 357 may be formed on sidewalls of the gate structures, and an impurity region may be formed at an upper portion of the substrate 300. For example, a spacer layer covering the gate structures may be formed of silicon nitride, and the spacer layer may be anisotropically etched to form the gate spacer 357.

In an example embodiment of the present inventive concept, an upper portion of the substrate 300 may be exposed between the gate spacers 357 formed on the cell region and the selection region, because a distance between the gate structures on the cell region and the selection region may be relatively large. Impurities may be provided in the upper portion of the substrate 300 by an ion-implantation process to form first and second impurity regions 303 and 307. For example, the first and second impurity regions 303 and 307 may extend linearly in the second direction.

A first insulating interlayer 360 covering the gate structures and the gate spacers 357 may be formed. The first insulating interlayer 360 may be formed of silicon oxide, such as, e.g., PEOX-based, TEOS-based or silicate glass-based materials.

A first plug 365 may be formed through the first insulating interlayer 360 to be in contact with or electrically connected to the first impurity region 303. For example, the first insulating interlayer 360 may be partially etched to form a first contact hole exposing the first impurity region 303. A first conductive layer filling the first contact hole may be formed on the first insulating interlayer 360, and an upper portion of the first conductive layer may be planarized by, e.g., a CMP process to form the first plug 365. The first plug 365 may serve as a common source line (CSL) contact of the semiconductor device.

In an example embodiment of the present inventive concept, a CSL electrically connected to the first plug 365 may be further formed on the first insulating interlayer 360.

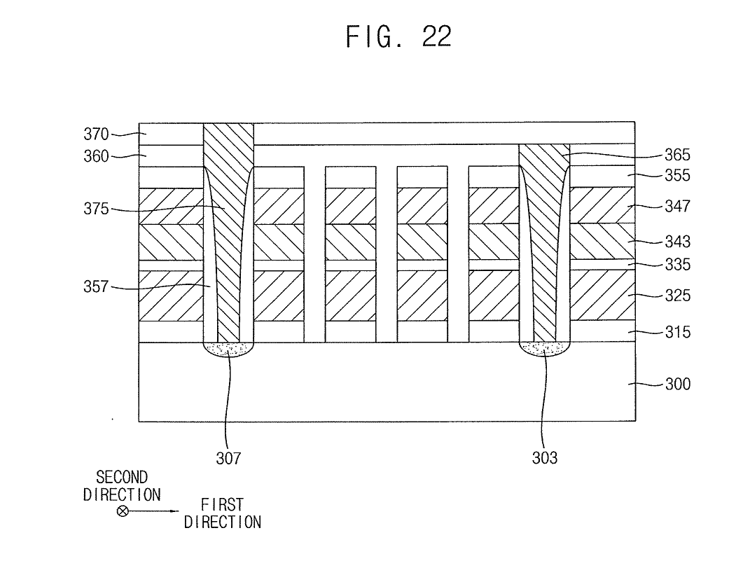

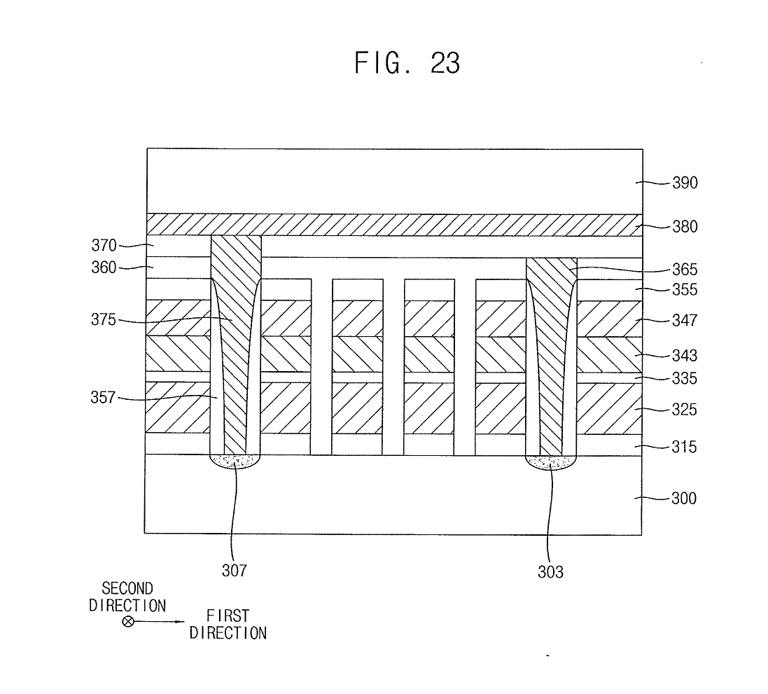

Referring to FIG. 22, a second insulating interlayer 370 may be formed on the first insulating interlayer 360 to cover the first plug 365. The second insulating interlayer 370 and the first insulating interlayer 360 may be partially etched to form a second contact hole exposing the second impurity region 307. A second conductive layer filling the second contact hole may be formed on the second insulating interlayer 370, and an upper portion of the second conductive layer may be planarized by a CMP process to form a second plug 375.

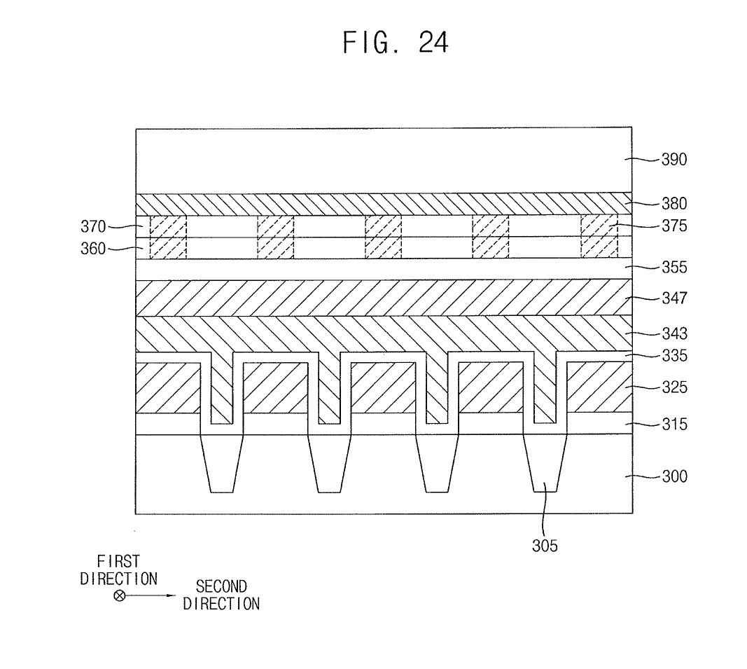

Referring to FIGS. 23 and 24, a third conductive layer 380 may be formed on the second insulating interlayer 370 and the second plugs 375, and a photoresist layer 390 may be formed on the third conductive layer 380.

In an example embodiment of the present inventive concept, the third conductive layer 380 may be formed of a metal such as, e.g., copper, tungsten, aluminum by a sputtering process or an ALD process.

The photoresist layer 390 may be formed from a process and a photoresist composition substantially the same as or similar to those described with reference to FIG. 2. The photoresist layer 390 may be formed directly on a top surface of the third conductive layer 380, and an additional layer including an anti-reflective layer may be omitted. In an example embodiment of the present inventive concept, the photoresist layer 390 may be formed as a multi-layered structure including first and second photoresist layers as described with reference to FIG. 7.

As described above, the photoresist composition may include a photosensitive resin, a PAG and a solvent. The photosensitive resin may include a blend of a dye resin and a photoresist polymer, or a photoresist polymer incorporated with a dye unit.

In an example embodiment of the present inventive concept, a PHS-based polymer including a repeating unit as represented by the Chemical Formula 1 above may be utilized as the photoresist polymer. The PHS-based polymer may include a styrene repeating unit and an acid-labile repeating unit containing an acid-labile protecting group.

In an example embodiment of the present inventive concept, a novolac-based resin including a repeating unit represented by the Chemical Formula 2 above may be used as the dye resin. The dye unit may include a novolac unit.

If the photosensitive resin includes a blend of the photoresist polymer and the dye resin, an amount of the dye resin may be in a range from about 20 wt % to about 80 wt % based on a total weight of the photosensitive resin.

If the photosensitive resin includes the photoresist polymer integrally incorporated with the dye unit, the novolac unit may be combined to at least one aryl ring included in the PHS-based polymer as represented by the Chemical Formula 3 above.

The photoresist composition may further include an acid quencher, and may further include an additive such as a sensitizer and/or a surfactant.

In an example embodiment of the present inventive concept, the photoresist composition may include the photosensitive resin in a range from about 5 wt % to about 20 wt %, the PAG in a range from about 0.1 wt % to about 1 wt %, the acid quencher in a range from about 0.01 wt % to about 0.5 wt %, the additive in a range from about 0.01 wt % to about 1 wt %, and the solvent in a range from about 78 wt % to about 94 wt %.

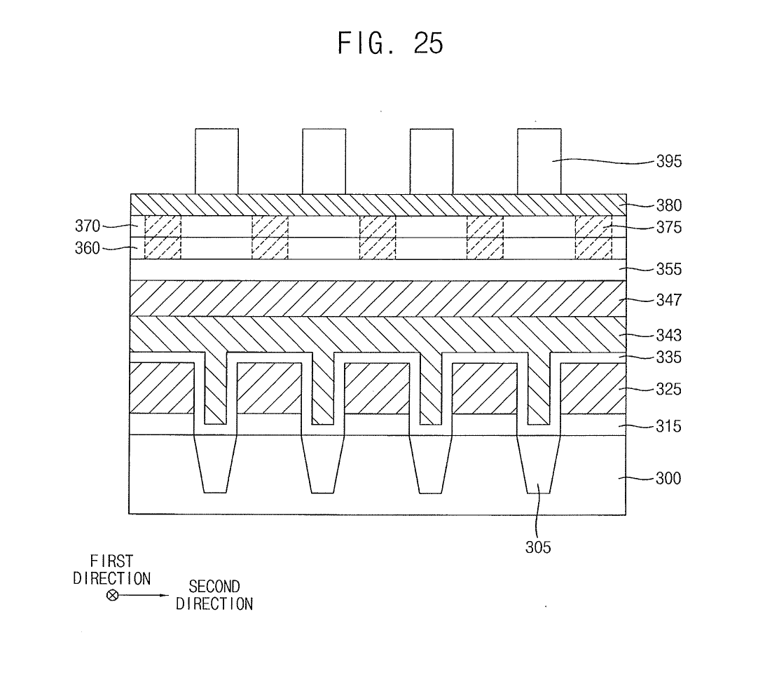

Referring to FIG. 25, process substantially the same as or similar to those illustrated with reference to FIGS. 3A and 4 may be performed. In an example embodiment of the present inventive concept, the photoresist layer 390 may be partially removed by exposure and developing processes. For example, an exposed portion of the photoresist layer 390 may be removed to form a photoresist pattern 395.

While performing the exposure process, a diffusively reflected light may be absorbed by the dye resin or the dye unit included in the photosensitive resin so that the photoresist patterns 395 may achieve high resolution.

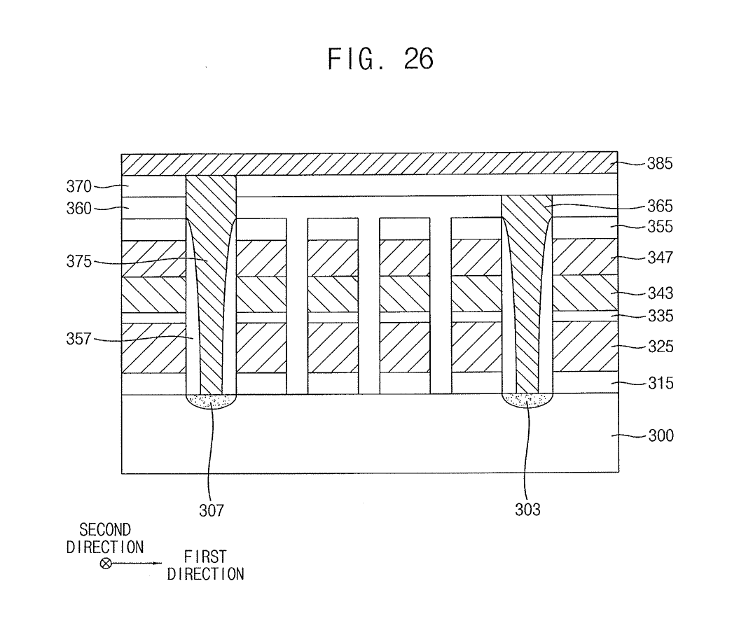

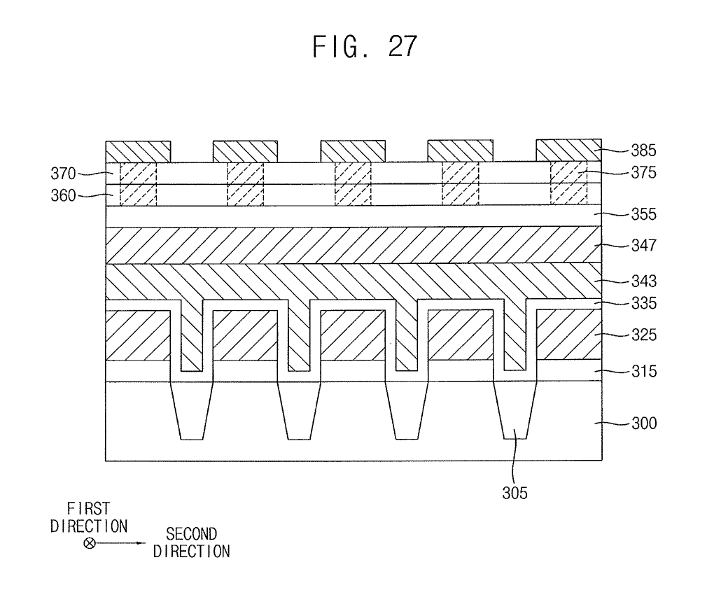

Referring to FIGS. 26 and 27, the third conductive layer 380 may be patterned using the photoresist pattern 395 as an etching mask. Accordingly, a conductive line 385 electrically connected to the second plug 375 may be formed from the third conductive layer 380.

The conductive line 385 may extend in, e.g., the first direction, and a plurality of the conductive lines 385 may be formed along the second direction. For example, the conductive line 385 may serve as a bit line of the semiconductor device.

In an example embodiment of the present inventive concept, wirings electrically connected to the second control gate 347 and/or the first control gate 343 of the gate structure may be further formed. The wirings may be also formed by a photo-lithography process using the photoresist composition according to an example embodiment of the present inventive concept, and using a metal layer as an object layer.

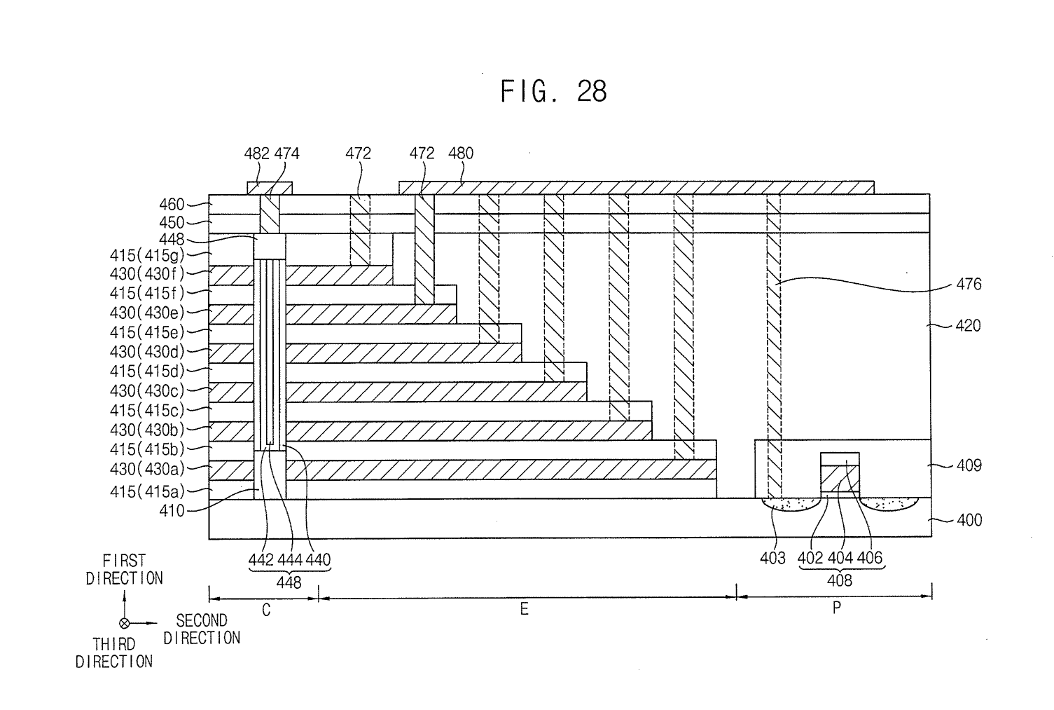

FIG. 28 is a cross-sectional view illustrating a semiconductor device in accordance with an example embodiment of the present inventive concept. For example, FIG. 28 illustrates a 3-dimensional non-volatile memory device.

In FIG. 28, a direction substantially vertical to a top surface of a substrate is referred to as a first direction, and two directions substantially parallel to the top surface of the substrate and perpendicular to each other are referred to as a second direction and a third direction.

Referring to FIG. 28, the semiconductor device may include gate lines 430 (e.g., 430a through 430f) and insulating interlayer patterns 415 (e.g., 415a through 415g) alternately and repeatedly stacked along the first direction from a top surface of a substrate 400.

The substrate 400 may include a cell region C, an extension region E and a peripheral region P. The gate lines 430 and the insulating interlayer patterns 415 may be stacked throughout the cell region C and the extension region E as a stepped shape or a pyramidal shape.

A vertical channel structure may be formed through the gate lines 430 and the insulating interlayer patterns 415 on the cell region C of the substrate 400. The vertical channel structure may include a semiconductor pattern 410 contacting the top surface of the substrate 400, and a dielectric layer structure 440, a channel 442 and a filling insulation pattern 444 formed on the semiconductor pattern 410. The vertical channel structure may further include a pad 448 at an upper portion thereof.

The gate line 430 may surround outer sidewalls of the dielectric layer structures 440 included in a plurality of vertical channel structures, and may extend in the second direction.

A gate structure 408 including a gate insulation pattern 402, a gate electrode 404 and a gate mask 406 may be formed on the peripheral region P of the substrate 400. An impurity region 403 may be formed at an upper portion of the substrate 400 adjacent to the gate structure 408. A peripheral circuit transistor may be defined by the gate structure 408 and the impurity region 403, and a peripheral circuit protection layer 409 covering the peripheral circuit transistor may be formed on the peripheral region P.

A mold protection layer 420 may be formed on the substrate 400 to cover the peripheral circuit protection layer 409, and a lateral portion of a stack structure including the insulating interlayer patterns 415 and the gate lines 430. A first upper insulation layer 450 covering an uppermost insulating interlayer pattern 415g and the pads 448 may be formed on the mold protection layer 420.

In an example embodiment of the present inventive concept, a cutting pattern may be formed through the first upper insulation layer 450, the stack structure and the mold protection layer 420 in the first direction.

A second upper insulation layer 460 may be formed on the first upper insulation layer 450 and the cutting pattern. Subsequently, contacts extending through the second upper insulation layer 460, the first upper insulation layer 450, the insulating interlayer pattern 415 and/or the mold protection layer 420 may be formed.

In an example embodiment of the present inventive concept, a first contact 474 electrically connected to the pad 448 may be formed through the second and first upper insulation layers 460 and 450. For example, the first contact 474 may serve as a bit line contact.

Second contacts 472 eclectically connected to the gate line 430 at each level may be formed through the second upper insulation layer 460, the first upper insulation layer 450, the insulating interlayer pattern 415 and the mold protection layer 420 on the extension region E. A third contact 476 electrically connected to the impurity region 403 may be formed through the second upper insulation layer 460, the first upper insulation layer 450, the mold protection layer 420 and the peripheral circuit protection layer 409 on the peripheral region P.

Wirings electrically connected to the contacts may be formed on the second upper insulation layer 460. For example, a metal layer may be formed on the second upper insulation layer 460, and a photoresist layer may be formed on the metal layer.

The photoresist layer may be formed from a process and a photoresist composition substantially the same as or similar to those described with reference to FIG. 2. Subsequently, process substantially the same as or similar to those illustrated with reference to FIGS. 3A and 4 may be performed. In an example embodiment of the present inventive concept, the photoresist layer may be partially removed by exposure and developing processes. For example, an exposed portion of the photoresist layer may be removed to form a photoresist pattern.

While performing the exposure process, a diffusively reflected light may be absorbed by a dye resin or a dye unit included in a photosensitive resin of the photoresist layer so that the photoresist pattern may achieve high resolution.

The metal layer may be partially etched using the photoresist pattern as an etching mask to form the wirings.

In an example embodiment of the present inventive concept, a first wiring 482 electrically connected to the first contact 474 may be formed on the cell region C. The first wiring 482 may extend in, e.g., the third direction, and may serve as a bit line.

A second wiring 480 electrically connected to the gate line 430 at each level via the second contact 472 may be formed on the extension region E. The second wiring 480 may serve as a signal wiring supplying a predetermined voltage to the gate line 430 at each level. The second wiring 480 may also extend on the peripheral region P to be electrically connected to the third contact 476.

As described above, in fabricating the planar-type or the 3-dimensional type non-volatile memory device, a photo-lithography process may be implemented using the photoresist composition according to an example embodiment of the present invention. Thus, a wiring having a fine pitch and a fine dimension may be achieved while preventing a reduction of resolution due to a diffusively reflected light.

Hereinafter, properties of a photoresist composition according to an example embodiment of the present inventive concept will be described in more detail with reference to

### EXPERIMENTAL EXAMPLE

### Experimental Example

A photoresist composition was coated on an aluminum substrate having a thickness of 5,500 Å, and was baked to form a photoresist layer having a thickness of 0.8 μm. The photoresist composition included a blend of a commercially available PHS resin and a novolac resin. A diazonium salt was used as a PAG

An exposure process was performed using the light generated from a KrF light source, and a PEB process was performed at 110° C. for 50 seconds. The exposed photoresist layer was immersed in a 0.261N TMAH aqueous developer solution (2.38%) to remove an exposed portion, and a photoresist pattern was obtained.

The above procedure was repeated with different contents (wt %) of the PHS resin and the novolac resin in the blend (as listed in Table 1 below), and a surface profile of each photoresist pattern was observed.

TABLE 1

| | Comparative | Example 1 | Example 2 | Example 3 |
|---|---|---|---|---|
| | Example (wt %) | (wt %) | (wt %) | (wt %) |
| PHS resin | 100 | 75 | 50 | 25 |
| novolac resin | 0 | 25 | 50 | 75 |

In Comparative Example devoid of a dye resin (novolac resin) in the photoresist composition, the photoresist pattern had irregular pitch and line width due to a reduced resolution by a diffused reflection.

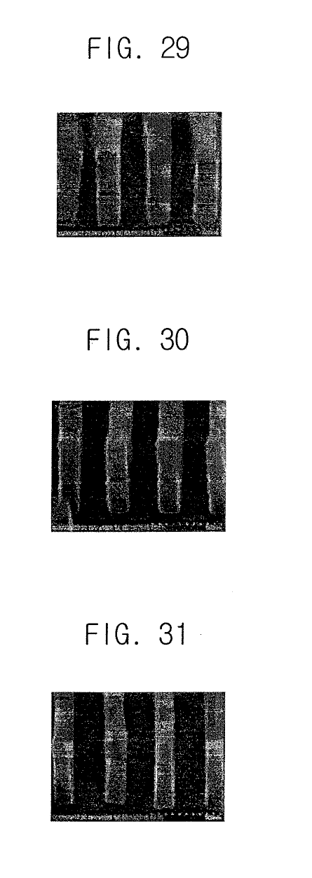

FIGS. 29, 30 and 31 are images of photoresist patterns formed using photoresist compositions of Examples 1, 2 and 3, respectively.

Referring to FIGS. 29 to 31, the photoresist patterns having substantially uniform line width and pitch were achieved by an addition of the novolac resin to the photoresist composition. As the content of the novolac resin increased, a uniformity of a sidewall profile of the photoresist pattern was also enhanced.

According to an example embodiment of the present inventive concept, the photoresist composition may include a photosensitive resin in which a dye agent may be incorporated or blended. The photoresist composition may be directly coated on a metal layer. A diffusively reflected light from the metal layer may be absorbed by the dye agent during an exposure process. Thus, a reduction of the resolution may be effectively avoided even though an anti-reflective layer may not be formed on the metal layer.

The foregoing is illustrative of example embodiments of the present inventive concept and is not to be construed as limiting thereof. Although a few example embodiments of the present inventive concept have been described, those skilled in the art will readily appreciate that many modifications are possible in the example embodiments without materially departing from the novel teachings of the present inventive concept. Accordingly, all such modifications are intended to be included within the scope of the present inventive concept as defined in the claims. Therefore, it is to be understood that the foregoing is illustrative of various example embodiments of the present inventive concept and is not to be construed as limited to the specific example embodiments disclosed, and that modifications to the disclosed example embodiments, as well as other example embodiments, are intended to be included within the scope of the appended claims.

1. A photoresist composition comprising:
a photosensitive resin including a blend of a photoresist polymer and a dye resin, an amount of the dye resin being in a range from about 20 weight percent to about 80 weight percent based on a total weight of the photosensitive resin;
a photo-acid generator; and
a solvent.

2. The photoresist composition of claim 1, wherein the amount of the dye resin is in a range from about 25 weight percent to about 75 weight percent based on the total weight of the photosensitive resin.

3. The photoresist composition of claim 2, wherein the photoresist polymer includes a polyhydroxystyrene (PHS)-based polymer, and the dye resin includes a novolac-based resin.

4. The photoresist composition of claim 3, wherein the photoresist polymer includes a repeating unit represented by Chemical Formula 1, and the dye resin includes a repeating unit represented by Chemical Formula 2: 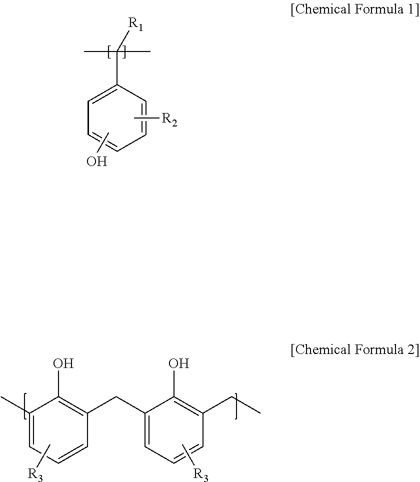
wherein, in Chemical Formula 1, R₁ is hydrogen or a C₁˜C₆ alkyl group, and R₂ is hydrogen, a C₁˜C₆ alkyl group, a C₃˜C₆ cycloalkyl group or a C₁˜C₆ alkoxy group, and wherein, in Chemical Formula 2, R₃ is independently hydrogen or a C₁˜C₆ alkyl group.

5. The photoresist composition of claim 4, wherein the photoresist polymer further includes a repeating unit including an acid-labile protecting group.

6. The photoresist composition of claim 1, wherein the photoresist composition is sensitive to a KrF excimer laser light, and the dye resin has a light-absorbent property to the KrF excimer laser light.

7. The photoresist composition of claim 1, wherein the photoresist composition is directly coated on a metal layer for patterning the metal layer.

8. The photoresist composition of claim 1, further comprising:
an acid quencher; and
an additive including at least one of a surfactant and a sensitizer,
wherein the photoresist composition includes the photosensitive resin in a range from about 5 weight percent to about 20 weight percent, the photo-acid generator in a range from about 0.1 weight percent to about 1 weight percent, the acid quencher in a range from about 0.01 weight percent to about 0.5 weight percent, the additive in a range from about 0.01 weight percent to about 1 weight percent, and the solvent in a range from about 78 weight percent to about 94 weight percent, based on a total weight of the photoresist composition.

9. A photoresist composition comprising:
a photosensitive resin including a photoresist polymer integrally combined with a novolac unit;
a photo-acid generator; and
a solvent.

10. The photoresist composition of claim 9, wherein the photoresist polymer includes a polyhydroxystyrene (PHS)-based polymer.

11. The photoresist composition of claim 10, wherein the novolac unit is combined to an aryl ring included in the PHS-based polymer.

12. The photoresist composition of claim 11, wherein the photoresist polymer further includes a linker group configured to connect the novolac unit to the aryl ring.

13. The photoresist composition of claim 12, wherein the photoresist polymer includes a repeating unit represented by Chemical Formula 3: 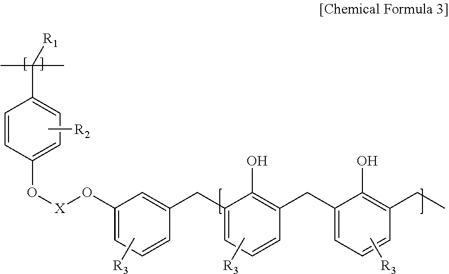
wherein, in Chemical Formula 3, R₁ is hydrogen or a C₁˜C₆ alkyl group, R₂ is hydrogen, a C₁˜C₆ alkyl group, a C₃˜C₆ cycloalkyl group or a C₁˜C₆ alkoxy group, R₃ is independently hydrogen or a C₁˜C₆ alkyl group, and
X represents the linker group, and includes a C₁˜C₁₀ alkyl group, a C₃˜C₁₀ cycloalkyl group, a C₁˜C₁₀ ether group, a C₃˜C₁₆ diether group or a combination thereof.

14. The photoresist composition of claim 10, wherein the novolac unit is combined to at least two aryl rings of the PHS-based polymer.

15. The photoresist composition of claim 11, wherein the novolac unit functions as a leaving group, and is separated from the PHS-based polymer by an acid generated from the photo-acid generator.

16. The photoresist composition of claim 9, wherein the novolac unit is combined with the photoresist polymer as a dye unit.

17. A method of forming a pattern comprising:
preparing a photoresist composition, the photoresist composition including a blend of a photoresist polymer and a dye resin, or a photoresist polymer integrally combined with a dye unit;
coating the photoresist composition directly on a metal layer to form a photoresist layer;
performing an exposure process on the photoresist layer to form a photoresist pattern; and
etching the metal layer using the photoresist pattern as an etching mask.

18. The method of claim 17, wherein the dye resin and the dye unit include a novolac-based resin and a novolac unit, respectively.

19. The method of claim 18, the photoresist polymer includes a polyhydroxystyrene (PHS)-based polymer.

20. The method of claim 17, the blend includes the dye resin in a range from about 20 weight percent to about 80 weight percent based on a total weigh of the blend.

21-33. (canceled)
